(19) United States
(12) Patent Application Publication
(10) Pub. No.: US 2020/0067454 A1
(43) Pub. Date: Feb. 27, 2020

(54) Vibrator, Oscillator, Electronic Device, And Vehicle

(71) Applicant: Seiko Epson Corporation, Tokyo (JP)

(72) Inventors: Masayuki KIKUSHIMA, Ina (JP); Manabu KONDO, Matsumoto (JP)

(21) Appl. No.: 16/546,738

(22) Filed: Aug. 21, 2019

(30) Foreign Application Priority Data
Aug. 22, 2018 (JP) 2018-155712

(51) Int. Cl. H03B 5/32; H01L 23/02; H01L 23/495; H01L 23/34; H03B 5/04; H01L 41/053; H03H 9/05

(52) U.S. Cl. CPC H03B 5/32; H01L 23/02; H01L 23/495; H03H 9/0547; H03B 5/04; H01L 41/053; H01L 23/34

(57) ABSTRACT

A vibrator includes a first substrate, a first lead frame provided in the first substrate, a package supported by the first lead frame, and a vibrating element housed in the package, in which the first lead frame has a first part coupled to the first substrate, a second part coupled to the package, and a third part coupling the first part with the second part, and including a curved portion, the first substrate has a first side and a second side opposite to each other in plan view, and a plurality of the first lead frames are provided at a side of the first side along the first side and provided at a side of the second side along the second side.

The present application is based on, and claims priority from, JP Application Serial Number 2018-155712, filed Aug. 22, 2018, the disclosure of which is hereby incorporated by reference herein in its entirety.

### BACKGROUND

### 1. Technical Field

The present disclosure relates to a vibrator, an oscillator, an electronic device, and a vehicle.

### 2. Related Art

A crystal oscillator is widely used as a frequency generating source for supplying a stable frequency, for example, a clock signal source in a broadcasting device, a measuring device, and a digital device. In particular, an oven controlled crystal oscillator (OCXO) houses a small heater and the crystal oscillator in a case to provide extremely good frequency stability by keeping an ambient temperature of a vibrator constant.

For example, JP-A-2016-131266 discloses a vibrator including a vibrating piece fixed onto a bottom plate of a package with a conductive adhesive in a cantilever form.

In the above-described vibrator, for example, when the vibrator is dropped, a frequency of the vibrating element can be largely changed or the vibrating element can be separated from the package due to an impact force.

### SUMMARY

A vibrator according to an aspect of the present disclosure includes a first substrate, a first lead frame provided in the first substrate, a package supported by the first lead frame, and a vibrating element housed in the package, in which the first lead frame has a first part coupled to the first substrate, a second part coupled to the package, and a third part coupling the first part with the second part, and including a curved portion, the first substrate has a first side and a second side opposite to each other in plan view, and a plurality of the first lead frames are provided at a side of the first side along the first side and provided at a side of the second side along the second side.

In the vibrator according to the aspect, in the first lead frame provided at the side of the first side, the first part and the second part may be positioned at the side of the second side from the curved portion in plan view, and in the first lead frame provided at the side of the second side, the first part and the second part may be positioned at the side of the first side from the curved portion in plan view.

In the vibrator according to the aspect, in the first lead frame provided at the side of the first side, the curved portion may be positioned at the side of the second side from the first part and the second part in plan view, and in the first lead frame provided at the side of the second side, the curved portion may be positioned at the side of the first side from the first part and the second part in plan view.

An oscillator according to another aspect of the present disclosure includes the vibrator of the aspect, a circuit element electrically coupled to the vibrator, and a heating element heating the vibrator.

The oscillator according to the aspect may further include a second substrate, and a second lead frame provided in the second substrate and supporting the first substrate, in which the first substrate has a third side and a fourth side intersecting with the first side and opposite to each other, in plan view, and a plurality of the second lead frames are provided at a side of the third side along the third side and provided at a side of the fourth side along the fourth side.

An oscillator according to another aspect of the present disclosure includes the vibrator of the aspect.

An electronic device according to another aspect of the present disclosure includes the vibrator of the aspect.

A vehicle according to an aspect of the present disclosure includes the vibrator of the aspect.

### BRIEF DESCRIPTION OF THE DRAWINGS

FIG. 1 is a cross-sectional view schematically illustrating an oscillator according to the present embodiment.

FIG. 2 is a perspective view schematically illustrating the oscillator according to the present embodiment.

FIG. 3 is a cross-sectional view schematically illustrating the oscillator according to the present embodiment.

FIG. 4 is a cross-sectional view schematically illustrating an oscillator according to a first modification example of the present embodiment.

FIG. 5 is a cross-sectional view schematically illustrating an oscillator according to a second modification example of the present embodiment.

FIG. 6 is a functional block diagram of an electronic device according to the present embodiment.

FIG. 7 is a view illustrating an example of a vehicle according to the present embodiment.

FIG. 8 is a cross-sectional view schematically illustrating a model used for simulation.

FIG. 9 is a perspective view schematically illustrating a model used for simulation.

FIG. 10 is a graph illustrating a relationship between an elapsed time and standardized equivalent stress.

### DESCRIPTION OF EXEMPLARY EMBODIMENTS

Hereinafter, preferred embodiments of the present disclosure will be described in detail with reference to the drawings. Note that, the embodiments described below are not intended to unduly limit the content of the present disclosure described in the appended claims. Further, all the configurations described below are not limited to necessarily essential components of the present disclosure.

### 1. Vibrator and Oscillator

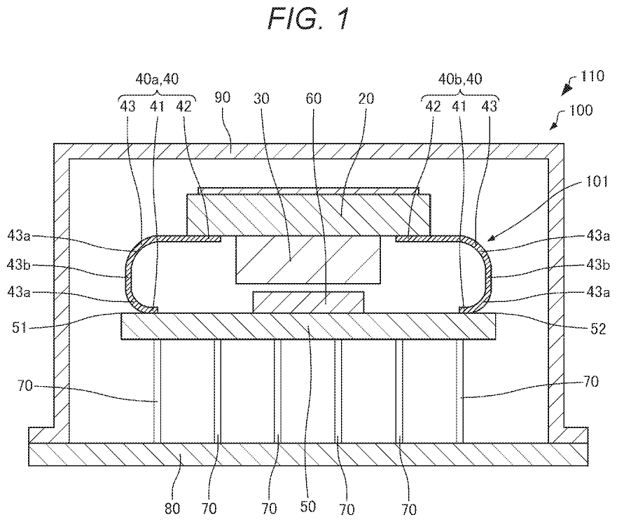

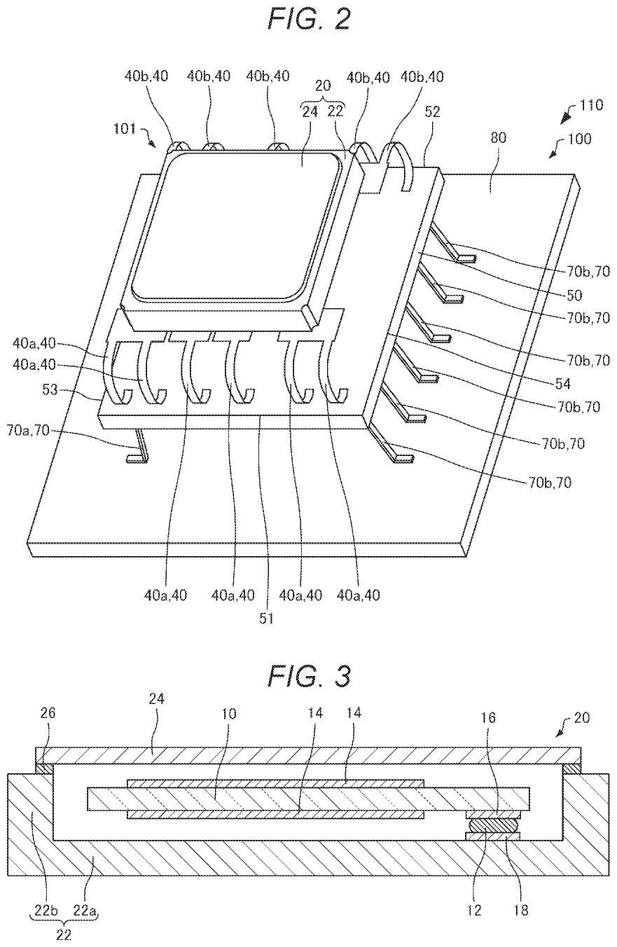

First, a vibrator and an oscillator according to the present embodiment will be described with reference to the drawings. FIG. 1 is a cross-sectional view schematically illustrating an oscillator 110 according to the present embodiment. FIG. 2 is a perspective view schematically illustrating the oscillator 110 according to the present embodiment. FIG. 3 is a cross-sectional view schematically illustrating the oscillator 110 according to the present embodiment.

As illustrated in FIGS. 1 to 3, the oscillator 110 includes a vibrator 100, a heating element 30, and a circuit element 60. For example, the vibrator 100 includes a vibrating element 10, a package 20, a first lead frame 40, a first substrate 50, a second lead frame 70, a second substrate 80, and a case 90.

For the convenience, in FIG. 1, the vibrating element 10 is not illustrated and the package 20 is illustrated in a simplified manner. In addition, the case 90 is not illustrated in FIG. 2. In addition, the heating element 30, the lead frames 40 and 70, the substrates 50 and 80, the circuit element 60, and the case 90 are not illustrated in FIG. 3.

As illustrated in FIG. 3, the vibrating element 10 is housed in the package 20. The vibrating element 10 vibrates, for example, with a thickness shear vibration as a main vibration. The vibrating element 10 has, for example, a disk shape. The vibrating element 10 may be formed by processing an SC cut crystal substrate or may be formed by processing an AT cut crystal substrate. A material of the vibrating element 10 may be a piezoelectric material such as lithium tantalate and lithium niobate.

For example, the vibrator 10 is provided on a bottom plate 22a of the package 20 with a conductive adhesive 12 in a cantilever form. The conductive adhesive 12 is, for example, a polyimide-based Ag paste.

Excitation electrodes 14 for vibrating the vibrating element 10 are provided on front and back surfaces of the vibrating element 10. The excitation electrode 14 is electrically coupled to an extraction electrode 16 provided on the vibrating element 10. For example, the excitation electrode 14 and the extraction electrode 16 formed by laminating chromium and gold in this order from a side of the vibrating element 10, are used. The extraction electrode 16 is electrically coupled to a connection electrode 18 provided on the package 20, through the conductive adhesive 12.

The package 20 houses the vibrating element 10. As illustrated in FIGS. 1 and 2, the package 20 is supported by the first lead frames 40. As illustrated in FIG. 3, the package 20 has a base 22 and a lid 24.

A material of the base 22 is, for example, ceramic. The base 22 may be formed by laminating and then sintering a green sheet having a predetermined shape. The base 22 has the plate-shaped bottom plate 22a and a side wall 22b provided on an upper surface of the bottom plate 22a at a peripheral portion. The vibrating element 10 is disposed in a recess portion defined by the bottom plate 22a and the side wall 22b.

For example, the lid 24 is joined to the side wall 22b by a seam ring 26 formed of an alloy such as Kovar. The lid 24 seals the recess portion defined by the bottom plate 22a and the side wall 22b in an airtight manner. A space housing the vibrating element 10 is formed by the lid 24 and the base 22. The space may be filled with an inert gas such as nitrogen gas, or in a pressure reduction state. A material of the lid 24 is, for example, Kovar.

As illustrated in FIGS. 1 and 2, the heating element 30 is provided on a lower surface of the package 20. The heating element 30 is joined to, for example, the lower surface of the package 20 by solder (not illustrated). In the example illustrated in FIGS. 1 and 2, the heating element 30 is not housed in the package 20. The heating element 30 is, for example, a heater. The heating element 30 heats the vibrating element 10 in the vibrator 100. The oscillator 110 is an OCXO including the heating element 30.

The first lead frame 40 supports the package 20. The first lead frame 40 is provided on the first substrate 50. The first lead frame 40 has conductivity. The excitation electrode 14 and the circuit element 60 are electrically coupled to each other through wiring (not illustrated) of the first substrate 50, the first lead frame 40, wiring (not illustrated) to which the first lead frame 40 and the connection electrode 18 are coupled, the connection electrode 18, the conductive adhesive 12, and the extraction electrode 16. A material of the first lead frame 40 is, for example, a Cu—Fe—P alloy, a Fe—Ni alloy, or the like. A surface of the first lead frame 40 may be plated with Au, Ag, Sn, Pd, solder, or the like.

The first lead frame 40 has, for example, a J-shape. As illustrated in FIG. 1, the first lead frame 40 has a first part 41, a second part 42, and a third part 43.

The first part 41 of the first lead frame 40 is coupled to the first substrate 50. The first part 41 is joined to, for example, an upper surface of the first substrate 50 by solder (not illustrated). In this case, the first part 41 is coupled to the upper surface of the first substrate 50 through the solder. For example, the first part 41 is not overlapped with the package 20 in plan view, that is, when viewed from a thickness direction (hereinafter, referred to as a “vertical direction”) of the first substrate 50.

The second part 42 of the first lead frame 40 is coupled to the package 20. The second part 42 is joined to, for example, the lower surface of the package 20 by solder (not illustrated). For example, the second part 42 is overlapped with the package 20 in plan view.

The third part 43 of the first lead frame 40 couples the first part 41 and the second part 42 to each other. For example, the third part 43 is not overlapped with the package 20 in plan view. The third part 43 has a curved portion 43a. In the example illustrated in FIG. 1, the third part 43 includes two curved portions 43a and a linear straight portion 43b to which the two curved portions 43a are coupled. Radius of curvature of the curved portion 43a is from 0.05 cm to 0.3 cm. Note that, the number of the curved portions 43a is not particularly limited.

As illustrated in FIG. 2, a plurality of the first lead frames 40 are provided. A first lead frame 40a among the plurality of first lead frames 40 is provided on a side of a first side 51 of the first substrate 50. A first lead frame 40b among the plurality of the first lead frames 40 is provided on a side of a second side 52 of the first substrate 50. A distance between the first lead frame 40a and the first side 51 is smaller than a distance between the first lead frame 40a and the second side 52 in plan view. A distance between the first lead frame 40b and the second side 52 is smaller than a distance between the first lead frame 40b and the first side 51 in plan view.

A plurality of first lead frames 40a are provided along the first side 51. A plurality of first lead frames 40b are provided along the second side 52. If the number of the first lead frames 40a and the number of the first lead frames 40b are plural, the numbers thereof are not particularly limited. The heating element 30 is provided between the first lead frame 40a and the first lead frame 40b.

In the first lead frame 40a, the first part 41 and the second part 42 are positioned at the side of the second side 52 from the curved portion 43a in plan view. In the first lead frame 40b, the first part 41 and the second part 42 are positioned at the side of the first side 51 from the curved portion 43a in plan view. Thus, the first lead frames 40a and 40b are curved outwardly.

In the first lead frame 40a, the third part 43 couples an end portion of the side of the first side 51 of the first part 41 and an end portion of the side of the first side 51 of the second part 42 to each other. In the first lead frame 40b, the third part 43 couples an end portion of the side of the second side 52 of the first part 41 and an end portion of the side of the second side 52 of the second part 42 to each other.

The first lead frame 40, the heating element 30, the package 20, and members housed in the package 20 such as the vibrating element 10 or the like constitute a structure 101. A natural frequency of the structure 101 in the vertical direction is smaller than a natural frequency of the vibrating element 10 in the vertical direction. The natural frequency of the structure 101 in the vertical direction is, for example, from one-tenth to one-fifth of the natural frequency of the vibrating element 10 in the vertical direction. Since the structure 101 has the first lead frame 40, the structure 101 can have a lower natural frequency. Note that, the natural frequency can be measured using a laser Doppler vibrometer (which is an optical heterodyne laser Doppler vibrometer manufactured by NEOARK Corporation).

The first substrate 50 is supported by the first lead frames 40. The first substrate 50 has the first side 51 and the second side 52 opposite to each other and a third side 53 and a fourth side 54 intersecting with the first side and opposite to each other, in plan view. A plane surface of the first substrate 50 has, for example, a rectangular shape, a square shape, or the like. The first substrate 50 is, for example, a printed circuit board.

The circuit element 60 is provided on the first substrate 50. The circuit element 60 is electrically coupled to the vibrator 100. The circuit element 60 includes an oscillation circuit for oscillating the vibrating element 10 and a control circuit for controlling a temperature of the heating element 30. In the example illustrated in FIGS. 1 and 2, the circuit element 60 and the heating element 30 are provided between the package 20 and the first substrate 50.

The second lead frame 70 supports the first substrate 50. The second lead frame 70 is provided on the second substrate 80. One end of the second lead frame 70 is joined to, for example, a lower surface of the first substrate 50 by solder (not illustrated). The other end of the second lead frame 70 is joined to, for example, an upper surface of the second substrate 80 by solder (not illustrated). A material of the second lead frame 70 is, for example, the same as that of the first lead frame 40.

As illustrated in FIG. 2, a plurality of the second lead frames 70 are provided. A second lead frame 70a among the plurality of second lead frames 70 is provided on a side of the third side 53 of the first substrate 50. A second lead frame 70b among the second lead frames 70 is provided on a side of the fourth side 54 of the first substrate 50. A distance between the second lead frame 70a and the third side 53 is smaller than a distance between the second lead frame 70a and the fourth side 54 in plan view. A distance between the second lead frame 70b and the fourth side 54 is smaller than a distance between the second lead frame 70b and the third side 53 in plan view.

A plurality of second lead frames 70a are provided along the third side 53. A plurality of second lead frames 70b are provided along the fourth side 54. If the number of the second lead frames 70a and the number of the second lead frames 70b are plural, the numbers thereof are not particularly limited.

The second substrate 80 is supported by the second lead frames 70. The second substrate 80 is, for example, a printed circuit board. The second substrate 80 is coupled to, for example, an external member (not illustrated).

The case 90 is joined to the second substrate 80. The case 90 is a recessed container capable of housing the package 20, the heating element 30, the lead frames 40 and 70, the first substrate 50, and the circuit element 60. A material of the case 90 is, for example, ceramic, glass, a metal, or the like.

The vibrator 100 and an oscillator 110 have, for example, characteristics as follows.

In the vibrator 100, the first lead frame 40 has the first part 41 coupled to the first substrate 50, the second part 42 coupled to the package 20, and the third part 43 to which the first part 41 and the second part 42 are coupled, including a curved portion. Therefore, for example, as compared to a case where the third part is provided from the first part to the second part in a linear shape, although the vibrator 100 is dropped, an impact force caused by the drop is absorbed and easily relaxed due to deformation of the third part 43 of the first lead frame 40. Further, in the vibrator 100, the plurality of first lead frames 40 are provided on the side of the first side 51 along the first side 51 and provided on the side of the second side 52 along the second side 52. Therefore, the impact force is absorbed and easily relaxed by the first lead frame 40. Accordingly, the vibrator 100 can have high impact resistance. Hence, even when the vibrator 100 is dropped, a frequency of the vibrating element 10 can be largely changed or the vibrating element can be separated from the package.

In the vibrator 100, the first lead frame 40a provided on the side of the first side 51 has the first part 41 and the second part 42 which are positioned at the side of the second side 52 from the curved portion 43a in plan view. In the vibrator 100, the first lead frame 40b provided on the side of the second side 52 has the first part 41 and the second part 42 which are positioned at the side of the first side 51 from the curved portion 43a in plan view. Thus, the first lead frames 40a and 40b are curved outwardly. Therefore, a space is easily formed between the first lead frame 40a and the first lead frame 40b in the vibrator 100, as compared with a case where the first lead frames are curved inwardly. Therefore, for example, the heating element 30 can be disposed between the first lead frame 40a and the first lead frame 40b as illustrated in FIG. 1.

The oscillator 110 includes the vibrator 100, the circuit element 60 electrically coupled to the vibrator 100, and the heating element 30 heating the vibrator 100. Therefore, in the oscillator 110, change in the frequency can be suppressed due to change in temperature of use environment, and frequency stability can be enhanced. Further, since the vibrator 100 has high impact resistance, the oscillator 110 can stably output a reference signal.

In the oscillator 110, the plurality of second lead frames 70 are provided on the side of the third side 53 along the third side 53, and provided on the side of the fourth side 54 along the fourth side 54. Therefore, the oscillator 110 can absorb the impact force caused by the drop by the second lead frame 70. Further, in the vibrator 100, a distance between the first part 41 of the first lead frame 40 and a portion coupled to the first substrate 50 of the second lead frame 70 can be increased as compared with a case where the plurality of second lead frames are provided on the side of the first side along the first side and provided on the side of the second side along the second side. Therefore, heat from the heating element 30 is transmitted through the first lead frame 40 and the second lead frame 70, and it is difficult to radiate the heat to the outside from the second substrate 80. Accordingly, the vibrator 100 of the oscillator 110 is easily heated at a desired temperature.

In the example described above, although it is described a case where the oscillator 110 is an OCXO, the oscillator according to the present disclosure may be a temperature compensated crystal oscillator (TCXO).

### 2. Modification Examples of Oscillator

### 2.1. First Modification Example

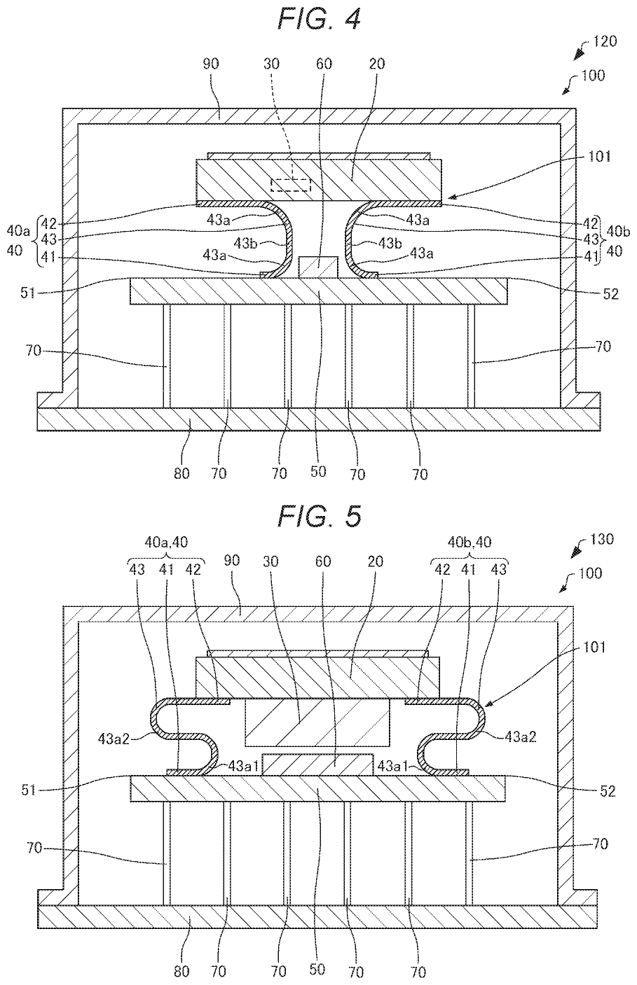

Next, an oscillator 120 according to a first modification example of the present embodiment will be described with reference to the drawings. FIG. 4 is a cross-sectional view schematically illustrating the oscillator 120 according to the first modification example of the present embodiment. Hereinafter, the oscillator 120 according to the first modification example of the present embodiment will be described unlike the example of the oscillator 110 according to the embodiment described above, and the same description will be omitted.

As shown in FIG. 1, the first lead frame 40 in the oscillator 110 described above is curved outwardly. On the other hand, the first lead frame 40 in the oscillator 120 is curved inwardly as shown in FIG. 4.

In the oscillator 120, the first lead frame 40a provided on the side of the first side 51 has the curved portion 43a which is positioned at the side of the second side 52 from the first part 41 and the second part 42 in plan view. The first lead frame 40b provided on the side of the second side 52 has the curved portion 43a which is positioned at the side of the first side 51 from the first part 41 and the second part 42 in plan view. In the example illustrated in FIG. 4, the third part 43 is positioned between the package 20 and the first substrate 50.

In the first lead frame 40a, the third part 43 couples an end portion of the side of the second side 52 of the first part 41 and an end portion of the side of the second side 52 of the second part 42 to each other. In the first lead frame 40b, the third part 43 couples an end portion of the side of the first side 51 of the first part 41 and an end portion of the side of the first side 51 of the second part 42 to each other. In the example illustrated in FIG. 4, the heating element 30 is housed in the package 20.

The first lead frame 40 in the oscillator 120 is curved inwardly. Therefore, the oscillator 120 can achieve reduction in size as compared with a case where the first lead frame is curved outwardly.

### 2.2. Second Modification Example

Next, an oscillator 130 according to a second modification example of the present embodiment will be described with reference to the drawings. FIG. 5 is a cross-sectional view schematically illustrating the oscillator 130 according to the second modification example of the present embodiment. Hereinafter, the oscillator 130 according to the second modification example of the present embodiment will be described unlike the example of the oscillator 110 according to the embodiment described above, and the same description will be omitted.

In the oscillator 110 described above, the first lead frame 40 has a J-shape as illustrated in FIG. 1. On the other hand, the first lead frame 40 in the oscillator 130 has an S-shape as shown in FIG. 5.

In the oscillator 130, the first lead frame 40 extends in the vertical direction while reciprocating in a direction perpendicular to the vertical direction from the first substrate 50 to the package 20. In the example in FIG. 5, the third part 43 of the first lead frame 40 has a curved portion 43a1 curved inwardly and a curved portion 43a2 curved outwardly. Note that, the number of the curved portions 43a1 and the number of the curved portions 43a2 are not particularly limited.

In the oscillator 130, the first lead frame 40 has an S-shape. Therefore, the oscillator 130 can increase, for example, the total length of the first lead frame 40 as compared with a case where the first lead frame has a J-shape. Accordingly, the oscillator 130 can more absorb the impact force by the first lead frame 40.

### 3. Electronic Device

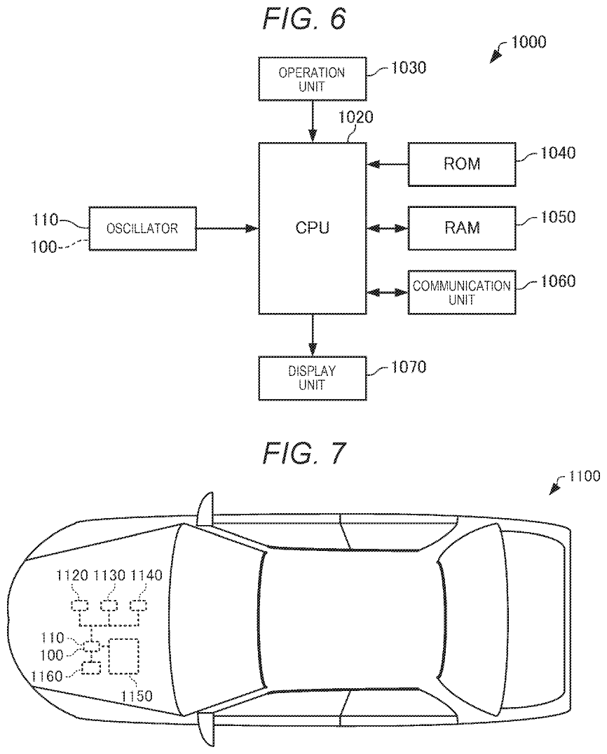

Next, an electronic device 1000 according to the present embodiment will be described with reference to the drawings. FIG. 6 is a functional block diagram of the electronic device 1000 according to the present embodiment.

As illustrated in FIG. 6, the electronic device 1000 includes the oscillator 110 having the vibrator 100, a central processing unit (CPU) 1020, an operation unit 1030, a read only memory (ROM) 1040, a random access memory (RAM) 1050, a communication unit 1060, and a display unit 1070.

The oscillator 110 generates an oscillation signal based on the oscillation of the vibrating element 10 heated by the heating element 30. The oscillation signal is output to the CPU 1020.

The CPU 1020 performs various calculation processing and control processing using the oscillation signal received from the oscillator 110 as a clock signal according to a program stored in the ROM 1040 or the like. In detail, the CPU 1020 performs various processing according to an operation signal received from the operation unit 1030, processing of controlling the communication unit 1060 for data communication with an external device, and processing of transmitting a display signal for displaying various types of information on the display unit 1070, and the like.

The operation unit 1030 is an input device constituted by an operation key, a button switch, or the like, and outputs the operation signal according to the operation of a user to the CPU 1020.

The ROM 1040 stores a program, data, or the like for performing, by the CPU 1020, the various calculation processing and control processing.

The RAM 1050 is used as a working area of the CPU 1020, and temporarily stores a program or data read from the ROM 1040, data received from the operation unit 1030, an arithmetic result obtained by performing various programs by the CPU 1020 and the like.

The communication unit 1060 performs various controls for establishing data communication between the CPU 1020 and the external device.

The display unit 1070 is a display device constituted by a liquid crystal display (LCD) or the like, and displays various types of information based on the display signal received from the CPU 1020. A touch panel functioning as the operation unit 1030 may be provided in the display unit 1070.

Various types of electronic device are considered as the electronic device 1000, and examples thereof include mobile terminals such as a mobile personal computer, a laptop personal computer, a tablet personal computer, a smartphone, a mobile phone, and the like, storage area network devices such as a digital camera, an ink jet printer, a router, a switch, and the like, a local area network device, a device for mobile terminal base station, a television, a video camera, a video recorder, a car navigation device, a real-time clock device, a pager, an electronic notebook, an electronic dictionary, a calculator, an electronic game equipment, a game controller, a word processor, a workstation, a video phone, a television monitor for security, an electronic binoculars, a POS terminal, a medical device, a fish detector, various measurement devices, instruments, a flight simulator, a head mount display, motion trace, motion tracking, a motion controller, pedestrian reckoning (PDR), and the like.

In addition, an example of the electronic device 1000 includes a transmission device functioning as a device for terminal base station performing communication with a terminal in a wired and wireless manner, using the oscillator 110 as a reference signal source or a voltage controlled oscillator (VCO).

### 4. Vehicle

Next, a vehicle according to the present embodiment will be described with reference to the drawings. FIG. 7 is a view illustrating an example of the vehicle according to the present embodiment.

A vehicle 1100 includes, for example, the oscillator 110 having the vibrator 100, controllers 1120, 1130, and 1140 for performing various controls such as an engine system, a brake system, a keyless entry system, and the like, a battery 1150, a backup battery 1160, and the like.

The oscillator 110 generates an oscillation signal based on the oscillation of the vibrating element 10 heated by the heating element 30. The oscillation signal is output from the oscillator 110 to the controllers 1120, 1130, and 1140 to use the oscillation signal as, for example, a clock signal.

The battery 1150 supplies electric power to the oscillator 110 and the controllers 1120, 1130, and 1140. The backup battery 1160 supplies electric power to the oscillator 110 and the controllers 1120, 1130, and 1140 when an output voltage of the battery 1150 is lower than a threshold value.

Various types of vehicle are considered as the vehicle 1100, and examples thereof include an automobile, aircrafts such as a jet plane and a helicopter, a ship, a rocket, a satellite, and the like.

### 5. Experimental Example

Hereinafter, experimental examples are shown and described in detail by the present disclosure. The present disclosure is not intended to be limited by the following experimental examples.

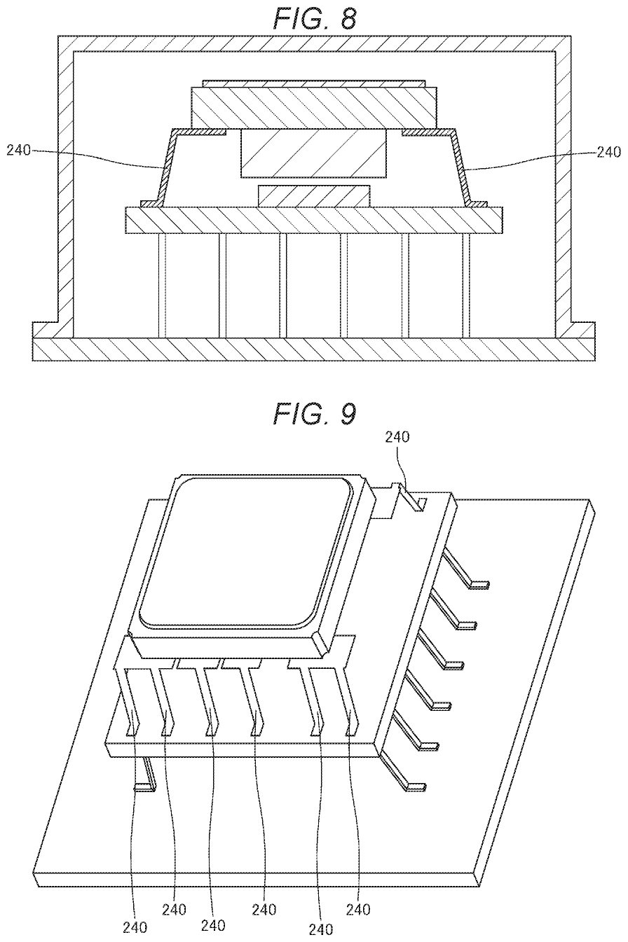

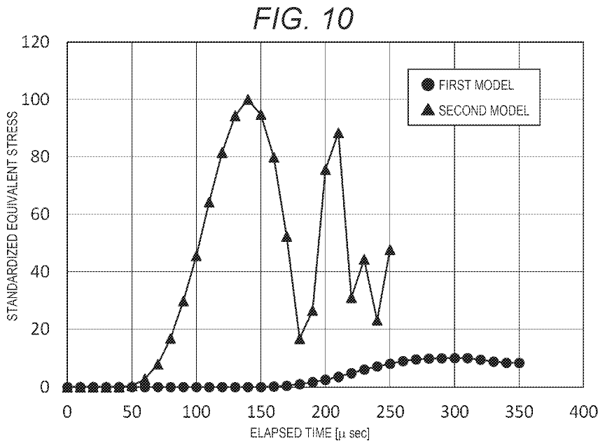

Impact resistance due to drop was examined according to the simulation by a finite element method. The simulation was performed using a first model and a second model. The first model corresponds to the oscillator 110 as illustrated in FIGS. 1 to 3. The second model is illustrated in FIGS. 8 and 9. A first lead frame 240 of the second model has a shape different from that of the first lead frame of the first model, and does not have a curved portion like the first model.

FIG. 8 is a cross-sectional view schematically illustrating the second model FIG. 9 is a perspective view schematically illustrating the second model. For the convenience, a case housing the vibrating element or the like is not illustrated in FIG. 9.

The above-described first and second models were naturally dropped at a point from tens of centimeters in height toward a rigid plate and collided with the rigid plate after 50 μsec later from the start of the drop. Further, equivalent stress generated in the conductive adhesive joining the vibrating element to the package due to the collision, is calculated.

FIG. 10 is a graph illustrating a relationship between an elapsed time after the drop is started and a value obtained by standardizing equivalent stress generated in the conductive adhesive. A horizontal axis indicates the elapsed time of the start of the drop as 0 μsec. A vertical axis indicates the standardized equivalent stress generated in the conductive adhesive of the second model and having the maximum value thereof as 100.

As illustrated in FIG. 10, the first model has a smaller equivalent stress than the second model, and the maximum equivalent stress of the second model was one-tenth or less. This is caused by the shape of the first lead frame. It was known that, by FIG. 10, the first model has a higher impact resistance than the second model.

Actually, a test was performed by producing a product corresponding to the first model and a product corresponding to the second model. As a result, the vibrating element was not separated from the package although the product corresponding to the first model dropped at height from eight to ten times the product corresponding to the second product.

The first and second models calculated the natural frequency of the vibrating element and the natural frequency of the structure including the first lead frame, the heating element, the package, and the vibrating element. The natural frequency is a natural frequency in the vertical direction.

In the first model, the natural frequency of the vibrating element was 4,700 Hz and the natural frequency of the structure was 670 Hz. In the second model, the natural frequency of the vibrating element was 4,700 Hz and the natural frequency of the structure was 4,060 Hz. It was known that the natural frequency of the structure in the first model was lower than the natural frequency of the structure in the second model.

The present disclosure may be configured to omit some of the configurations described above insofar as the features and effects described in the present specification, and may combine respective embodiments and modification examples.

The present disclosure is not limited to the above embodiments, and various modifications can be varied in many ways. For example, the present disclosure includes configurations that are substantially the same as the configurations described in the above embodiments. The substantially same configurations are the configurations that are substantially the same as the configuration having, for example, the same function, method, and results, or a configuration having the same objective and effects. In addition, the present disclosure includes a configuration in which an unsubstantial part described in the above embodiments is replaced by another part. In addition, the present disclosure includes a configuration having the same effects as those of the configurations described in the embodiments, or a configuration capable of achieving the same objective as that of the configurations described in the embodiments. In addition, the present disclosure includes a configuration in which a known technique is added to the configurations described in the embodiments.

What is claimed is:

1. A vibrator comprising:
a first substrate that has a first side and a second side opposite to each other in plan view;
a plurality of first lead frames provided on the first substrate and arranged along the first side of the first substrate or arranged along the second side of the first substrate;
a package supported by the first lead frames; and
a vibrating element housed in the package, wherein
each of the first lead frames has
a first part coupled to the first substrate,
a second part coupled to the package, and
a third part coupling the first part with the second part, and including a curved portion.

2. The vibrator according to claim 1, wherein
in the first lead frame provided at the first side of the first substrate, the first part and the second part are positioned between the curved portion and the second side of the first substrate in plan view, and
in the first lead frame provided at the second side of the first substrate, the first part and the second part are positioned between the curved portion and the first side of the first substrate in plan view.

3. The vibrator according to claim 1, wherein
in the first lead frame provided at the first side of the first substrate, the curved portion is positioned between the first part and the second side of the first substrate in plan view, and
in the first lead frame provided at the second side of the first substrate, the curved portion is positioned between the first part and the first side of the first substrate in plan view.

4. An oscillator comprising:
the vibrator according to claim 1;
a circuit element electrically coupled to the vibrator; and
a heating element heating the vibrator.

5. The oscillator according to claim 4, further comprising:
a second substrate that has a third side and a fourth side intersecting with the first side and opposite to each other, in plan view; and
a plurality of second lead frames provided on the second substrate and supporting the first substrate, wherein
the second lead frames are provided along the third side of the second substrate or provided along the fourth side of the second substrate.

6. An electronic device comprising the vibrator according to claim 1.

7. A vehicle comprising the vibrator according to claim 1.
